(19) United States
(12) Patent Application Publication
(10) Pub. No.: US 2025/0060426 A1
(43) Pub. Date: Feb. 20, 2025

(54) Electronic Devices With Optical Assembly Position Sensors

(71) Applicant: Apple Inc., Cupertino, CA (US)

(72) Inventors: Aaron D Johnson, Colfax, WA (US); Matin Seadat Beheshti, Sunnyvale, CA (US)

(21) Appl. No.: 18/755,068

(22) Filed: Jun. 26, 2024

Related U.S. Application Data
(60) Provisional application No. 63/519,605, filed on Aug. 15, 2023.

(51) Int. Cl. G01R 33/032; G02B 7/00; G02B 7/12; G02B 27/01

(52) U.S. Cl. CPC G01R 33/032; G02B 7/005; G02B 7/12; G02B 27/0176

(57) ABSTRACT

A head-mounted device may include optical assemblies for presenting images to a user. Each optical assembly may have a support configured to support a display, a lens through which an image from the display is presented to an eye box for viewing, and a sensor. Each support may have an opening configured to receive a guide rod along which the support slides to adjust where the optical assembly is positioned along that guide rod. Each guide rod may include a position index such as a strip-shaped index formed from alternating magnetic poles or alternating light and dark regions. A magnetic sensor or optical sensor may monitor the position index as the support slides along the guide rod to determine the position of the support and optical assembly along the guide rod.

This application claims the benefit of U.S. provisional patent application No. 63/519,605, filed Aug. 15, 2023, which is hereby incorporated by reference herein in its entirety.

### FIELD

This relates generally to electronic devices, and, more particularly, to electronic devices such as head-mounted devices.

### BACKGROUND

Electronic devices have components such as displays and lenses. It can be challenging to customize such devices for different users.

### SUMMARY

A head-mounted device may include optical assemblies for presenting images to a user. To accommodate users with different interpupillary distances, the optical assemblies may be moved together or apart.

Each optical assembly may have a support configured to support a display, a lens through which an image from the display is presented to an eye box for viewing, and a sensor. Each support may have an opening configured to receive a guide rod along which the support slides. Each guide rod may include a position index such as a strip-shaped index formed from alternating magnetic poles, alternating light and dark regions, or other suitable position index structures. A magnetic sensor or optical sensor may monitor the position index as the support slides along the guide rod to determine the position of the support and optical assembly along the guide rod. Relative and absolute position sensing techniques may be used.

### BRIEF DESCRIPTION OF THE DRAWINGS

FIG. 1 is a diagram of an illustrative head-mounted device in accordance with an embodiment.

FIG. 2 is a top view an illustrative optical assembly and guide rod in accordance with an embodiment.

FIG. 3 is a perspective view of an illustrative guide rod in accordance with an embodiment.

FIGS. 4, 5, 6, 7, 8, and 9 are cross-sectional end views of illustrative guide rods in accordance with embodiments.

FIG. 10 is a diagram of an illustrative single-track position index strip that may be included in a guide rod in accordance with an embodiment.

FIG. 11 is a diagram of an illustrative multiple-track position index strip that may be included in a guide rod in accordance with an embodiment.

FIG. 12 is a cross-sectional view of an illustrative multi-element sensor for reading position information from an associated guide rod multiple-track position index strip in accordance with an embodiment.

FIG. 13 is a diagram of an illustrative hybrid relative-absolute position index strip in accordance with an embodiment.

FIG. 14 is a diagram of an illustrative guide rod with a hybrid position index formed from embedded guide rod fibers and a series of discrete absolute position codes in accordance with an embodiment.

FIG. 15 is a cross-sectional end view of an illustrative portion of an optical assembly and associated guide rod showing how a sensor on the optical assembly may read position information from a strip-shaped position index on the guide rod in accordance with an embodiment.

### DETAILED DESCRIPTION

Electronic devices such as head-mounted devices may have displays for displaying images and lenses that are used in presenting the images to eye boxes for viewing by a user. Different users have different spacings between their eyes, which are sometimes referred to as interpupillary distances. To accommodate users with different interpupillary distances, a head-mounted device may be provided with movable optical assemblies.

A head-mounted device may have position sensors to measure the positions of the optical assemblies. This information may be used to accurately control the separation between the optical assemblies. In an illustrative embodiment, the optical assemblies may slide along guide rods during positioning operations and the position sensors may make position measurements using position addresses on the guide rods. The position addresses, which may sometimes be referred to as position codes, position markings, or position indices, may be formed using magnetic structures (e.g., a series of discrete magnets, magnetic domains formed in a strip of magnetic tape or other magnetic material, etc.), optical markings (e.g., codes, tic marks, one-dimensional and/or two-dimensional bar codes, or other optical indices that are measured using optical sensors), and/or other index structures (e.g., indices sensed using resistance sensors, capacitance sensors, force sensors, and/or other sensors). Configurations in which guide rods include magnetic and optical indices are sometimes described herein as an example.

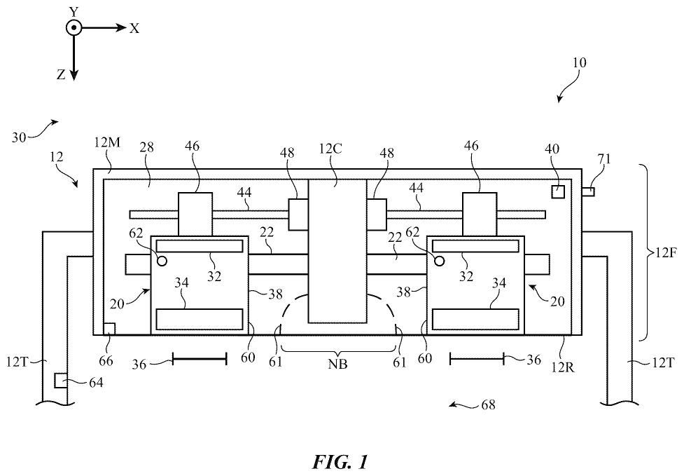

FIG. 1 is a schematic diagram of an illustrative electronic device of the type that may include movable optical assemblies to accommodate different interpupillary distances. Device 10 of FIG. 1 may be a head-mounted device (e.g., goggles, glasses, a helmet, and/or other head-mounted device). In an illustrative configuration, device 10 is a head-mounted device such as a pair of goggles (sometimes referred to as virtual reality goggles, mixed reality goggles, augmented reality glasses, etc.).

As shown in the illustrative cross-sectional top view of device 10 of FIG. 1, device 10 may have a housing such as housing 12 (sometimes referred to as a head-mounted support structure, head-mounted housing, or head-mounted support). Housing 12 may include a front portion such as front portion 12F and a rear portion such as rear portion 12R. When device 10 is worn on the head of a user, rear portion 12R rests against the face of the user and helps block stray light from reaching the eyes of the user and nose bridge portion NB of housing 12 rests on the nose of the user.

Main portion 12M of housing 12 may be attached to head strap 12T. Head strap 12T may be used to help mount main portion 12M on the head and face of a user. Main portion 12M may have a rigid shell formed from housing walls of polymer, glass, metal, and/or other materials. When housing 12 is being worn on the head of a user, the front of housing 12 may face outwardly away from the user, the rear of housing 12 (and rear portion 12R) may face towards the user. In this configuration, rear portion 12R may face the user's eyes located in eye boxes 36.

Device 10 may have electrical and optical components that are used in displaying images to eye boxes 36 when device 10 is being worn. These components may include left and right optical assemblies 20 (sometimes referred to as optical modules). Each optical assembly 20 may have an optical assembly support 38 (sometimes referred to as a lens barrel, optical module support, lens support, lens and display support, support, or support structure) and guide rods 22 (sometimes referred to as guide rails 22) along which optical assemblies 20 may slide to adjust optical-assembly-to-optical-assembly separation to accommodate different user interpupillary distances. Guide rods 22 may be cylindrical (e.g., guide rods 22 may have circular cross-sectional shapes) or may have other suitable shapes (e.g., rods 22 may have cross-sectional shapes that are triangular, rectangular, hexagonal, semi-circular, etc.). Cylindrical guide rods are sometimes described herein as an example.

Each assembly 20 may have a display 32 that has an array of pixels for displaying images and a lens 34. Lens 34 may optionally have a removable vision correction lens for correcting user vision defects (e.g., refractive errors such as nearsightedness, farsightedness, and/or astigmatism). In each assembly 20, display 32 and lens 34 may be coupled to and supported by support 38. During operation, images displayed by displays 32 may be presented to eye boxes 36 through lenses 34 for viewing by the user.

Rear portion 12R may include flexible structures (e.g., a flexible polymer layer, a flexible fabric layer, and/or other flexible housing structures) so that portion 12R can stretch to accommodate movement of supports 38 toward and away from each other to accommodate different user interpupillary distances. These flexible portions may sometimes be referred to as a curtain, stretchable fabric curtain, etc.

The walls of housing 12 may separate interior region 28 within device 10 from exterior region 30 surrounding device 10. In interior region 28, optical assemblies 20 may be mounted on guide rods 22. Supports 38 may have openings that receive guide rods 22 and that allow supports 38 and assemblies 20 to slide along guide rods 22 to adjust the spacing between assemblies 20. There may be one or more guide rods 22 for each support 38 (e.g., each support may receive upper and lower guide rods 22). Guide rods 22 may be attached to central housing portion 12C. If desired, the outer ends of guide rods 22 may be unsupported (e.g., the outer end portions of rods 22 may not directly contact housing 12, so that these ends float in interior region 28 with respect to housing 12).

Device 10 may include control circuitry and other components such as components 40. The control circuitry may include storage, processing circuitry formed from one or more microprocessors and/or other circuits. The control circuitry may be used to control any adjustable components in device 10 such as motors, actuators, displays, light-emitting components, audio components, etc. To support communications between device 10 and external equipment, the control circuitry may include wireless communications circuitry. Components 40 may include sensors such as such as force sensors (e.g., strain gauges, capacitive force sensors, resistive force sensors, etc.), audio sensors such as microphones, touch and/or proximity sensors such as capacitive sensors, optical sensors such as optical sensors that emit and detect light, ultrasonic sensors, and/or other touch sensors and/or proximity sensors, monochromatic and color ambient light sensors, image sensors, sensors for detecting position, orientation, and/or motion (e.g., accelerometers, magnetic sensors such as compass sensors, gyroscopes, and/or sensors such as inertial measurement units that contain some or all of these sensors), radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, visual inertial odometry sensors, current sensors, voltage sensors, and/or other sensors. In some arrangements, device 10 may use sensors to gather user input (e.g., button press input, touch input, etc.). Sensors may also be used in gathering environmental measurements (e.g., device motion measurements, temperature measurements, ambient light readings, etc.).

Optical assemblies 20 may have gaze trackers 62 (sometimes referred to as gaze tracker sensors). Gaze trackers 62, which may operate through lenses 34, may include one or more light sources such as infrared light-emitting diodes that emit infrared light to illuminate the eyes of a user in eye boxes 36. Gaze trackers 62 also include infrared cameras for capturing images of the user's eyes and measuring reflections (glints) of infrared light from each of the infrared light sources. By processing these eye images, gaze trackers 62 may track the user's eyes and determine the point-of-gaze of the user. Gaze trackers 62 may also measure the locations of the user's eyes (e.g., the user's eye relief and the user's interpupillary distance).

To accommodate users with different interpupillary distances (eye-to-eye spacings), the spacing between the left and right optical assemblies 20 in device 10 can be adjusted (e.g., to match or nearly match the user's measured interpupillary distance). Device 10 may have left and right actuators (e.g., motors) such as motors 48. Each motor 48, which may include internal gears, may be used to rotate an elongated threaded shaft (screw) such as shaft 44. A nut 46 may be provided on each shaft 44. The nut, which may, if desired, be formed from part of support 38, has threads that engage the threads on that shaft 44. When a shaft is rotated, the nut on the shaft is driven in a +X or −X direction (in accordance with whether the shaft is being rotated clockwise or counterclockwise). In turn, this moves the optical assembly 20 that is attached to the nut in the +X or −X direction along its optical assembly guide rod 22. Each assembly 20 (e.g., support 38) may have a portion that forms a cylindrical opening or other suitable structure that receives one of guide rods 22 so that the assembly is guided along the guide rod. By controlling the activity of motors 48, the spacing between the left and right optical assemblies of device 10 may be changed so that interpupillary distance adjustments can be made to device 10 to accommodate the interpupillary distances of different users. For example, if a user has closely spaced eyes, assemblies 20 may be moved inwardly (towards each other and towards nose bridge portion NB of housing 12) and if a user has widely spaced eyes, assemblies 20 may be moved outwardly (away from each other).

When device 10 is being worn by a user, the user's head is located in region 68. The presence of the user's head (and therefore a determination of whether device 10 is being worn or is unworn) may be made using one or more sensors (e.g., gaze trackers 62, which may detect the presence of the eyes of the user in eye boxes 36, rear-facing sensors such as sensor 66 on main portion 12M, head-facing sensors mounted on strap 12T such as sensor 64, and/or other head presence sensors). These sensors may include cameras, light sensors (e.g., visible light or infrared sensors that measure when ambient light levels have dropped due to shadowing by the head of a user), proximity sensors (e.g., sensors that emit light such as infrared light and that measure corresponding reflected light from a user's head with an infrared light sensor, capacitive proximity sensors, ultrasonic acoustic proximity sensors, etc.), switches and/or other force-sensing sensors that detect head pressure when a user's head is present, and/or other head presence sensors.

Output from head presence sensors and/or output from gaze trackers 62 may be used in controlling motors 48 to automatically adjust the spacing of optical assemblies 20. Optical assembly spacing may also be adjusted manually (e.g., by controlling motors 48 using a button such as button 71).

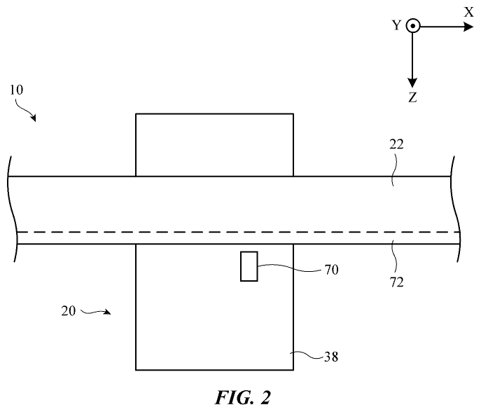

FIG. 2 is a top view of an interior portion of device 10 showing how support 38 of each optical assembly 20 may have an opening that receives a corresponding guide rod 22. A position sensor that measures the position of assembly 20 (e.g., that measures the position of support 38 along the length of guide rod 22) may be formed using sensor 70 and position index 72. Position index 72 may be, for example, a magnetic index having alternating north and south poles or other pattern of magnetic poles (magnetic domains) that can be measured by a magnetic sensor or may be an optical index formed from a series of light/dark patterns fabricated by ink printing, laser etching, scribing, and/or other optical index fabrication techniques. As sensor 70 moves along index 72, sensor 70 may measure magnetic field fluctuations as sensor 70 passes by the magnetic poles of index 72 (in embodiments in which index 72 is a magnetic index) or may measure light fluctuations as sensor 70 passes by the light and dark optical markings (or other optically visible markings) of index 72 (in embodiments in which index 72 is an optical index). In this way, index 72 serves as a reference that allows sensor 70 to accurately measure the location of sensor 70 along guide rod 22. Index 72 may be used in implementing a relative position sensor (e.g., a position sensor with a series of unmarked tic marks where position is determined by counting the number of tic marks passed by sensor 70), an absolute position sensor (e.g., a position sensor where addresses such as bar codes or other codes are used to provide sensor 70 with absolute position information so that sensor 70 need not count the number of tic marks being passed), or a hybrid position sensor (e.g., a position sensor that includes both relative sensor index structures such as tic marks and absolute position codes such as bar codes that give absolute position information). In a hybrid sensor, the absolute position codes (position addresses) may be interspersed within a row of tic marks that give relative position information at locations between the absolute position codes.

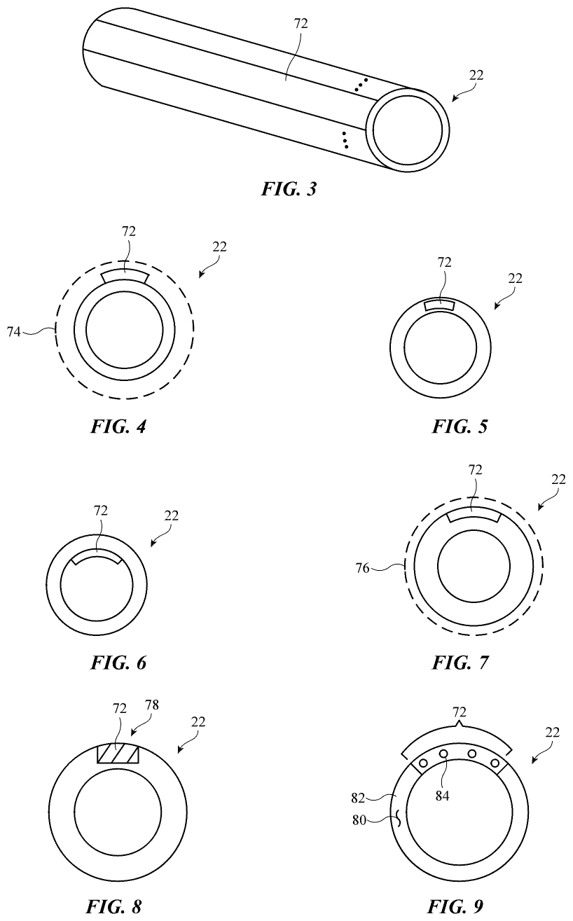

FIG. 3 is a perspective view of an illustrative guide rod. As shown in FIG. 3, guide rod 22 may be provided with a position index (e.g., index 72). Index 72 may have a strip shape and may extend along the length of guide rod 22. Index 72 may wrap only partway around the circumference of guide rod 22 or index 72 may wrap entirely around the circumference of guide rod 22.

FIGS. 4, 5, 6, 7, 8, and 9 are cross-sectional end views of illustrative guide rods. Guide rod 22 may be formed from a hollow cylindrical tube with a circular cross-sectional shape, a hollow tube of other cross-sectional shape (triangular, rectangular, hexagonal, semi-circular, etc.), or a solid rod (e.g., a solid cylindrical bar or a solid bar with other suitable shapes). Guide rod 22 may be formed from fiber-composite material (e.g., guide rod 22 may be a fiberglass rod or carbon-fiber rod formed from epoxy or other polymer filled with fibers such as glass fibers or carbon fibers), may be formed from polymer (e.g., polymer without embedded fibers), may be formed from ceramic, glass, metal, natural materials such as wood, other materials, and/or combinations of these materials.

In the example of FIG. 4, position index 72 has been formed on the surface of a hollow tube forming guide rod 22. An optional covering layer such as layer 74 may be formed over index 72. In an illustrative configuration, index 72 of FIG. 4 may be formed from a strip of polymer or other elongated substrate on which magnets, a coating of magnetic material with a desired pattern of magnetic poles for forming a magnetic index, or optical index marks have been formed and layer 74 may be a polymer coating (e.g., a cured coating of liquid polymer) for index 72 and rod 22 or a polymer tube that serves as a covering sleeve for index 72 and rod 22. Covering layers formed from one or more other materials (metal, glass, ceramic, etc.) may also be used, if desired. Covering layer 74 may be used to help protect index 72 from wear and/or to help reduce sliding friction as support 38 is moved along guide rod 22.

In the example of FIG. 5, index 72 has been embedded within the wall of guide rod 22. The wall of guide rod 22 may, for example, be formed from polymer (with or without strengthening embedded fibers).

FIG. 6 is a cross-sectional end view of guide rod 22 in an illustrative configuration in which index 72 has been formed on an inner surface of guide rod 22 (e.g., in the hollow cylindrical opening within a guide rod tube).

If desired, adhesive may be used in attaching index 72 to rod 22. Arrangements in which index 72 is formed as an integral portion of rod 22 may also be used.

In some embodiments, guide rod 22 may be formed using a pultrusion process in which guide rod materials are pulled through a pultrusion die. As an example, a pultrusion tool may be provided with fibers (e.g., glass or carbon fibers) and a liquid polymer (e.g., a thermoplastic or thermoset polymer in liquid form). A guide rod formed using this type of arrangement is shown in FIG. 7. As shown in FIG. 7, the materials that are pulled through the pultrusion tool may form a hollow guide rod with a fiber-composite wall covered with a thin coating of hardened liquid polymer such as coating 76. Index 72 may be formed in rod 22 of FIG. 7 under coating 76 (e.g., an index strip or other structures for forming index 72 may be fed into the input of the pultrusion tool with the fibers and liquid polymer as guide rod 22 is being pulled through the tool).

If desired, guide rod 22 may have a groove that runs along its length such as groove 78 of FIG. 8. Index 72 (e.g., a series of discrete magnets, a strip of magnetic material magnetized to form alternating north/south magnetic poles or other magnetic pole pattern for index 72, optical index structures such as a strip of polymer, metal, or other material with black and white optical tic marks or other light and dark markings) may be formed in groove 78. The surface of index 72 may be flush with the surface of rod 22 or may lie above or below the surface of rod 22. By recessing the outer surface of index 72 of FIG. 8 below the surface of guide rod 22, wear to index 72 may be avoided and sliding friction when moving support 38 along guide rod 22 may be reduced.

Another illustrative arrangement for providing guide rod 22 with a position index is shown in FIG. 9. In the example of FIG. 9, guide rod 22 has been provided with magnetic material 84 to form index 72. Index 72 of FIG. 9 may, as an example, have a strip shape that extends along the length of rod 22. Rod 22 may be formed from resin (e.g., rod 22 may have a tubular wall formed from polymer 82 in which fibers 80 (e.g., glass fibers or carbon fibers) are embedded. Material 84, which may be formed from magnetic particles such as ferromagnetic particles, may be incorporated into polymer 82 (e.g., during pultrusion operations or other operations in which rod 22 is formed) and subsequently magnetized using an external magnet to form a desired pattern of magnetic poles for index 72.

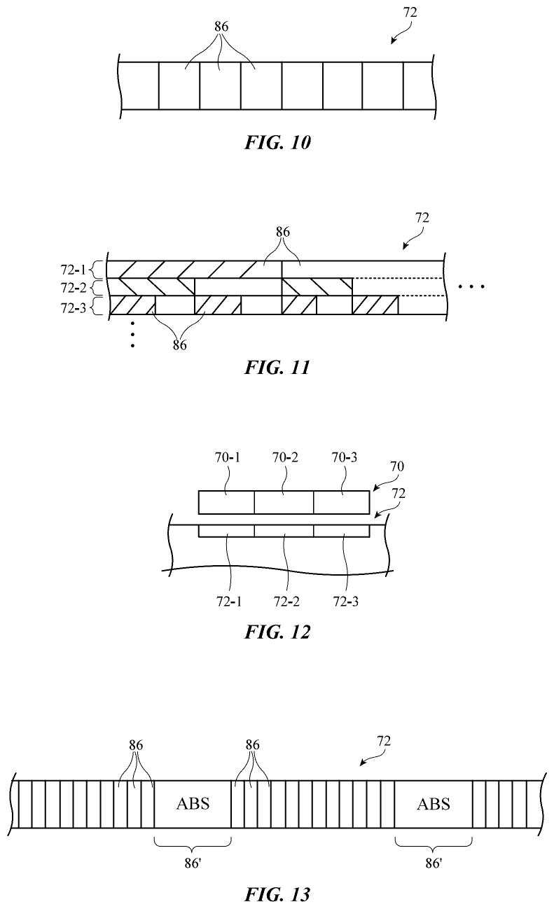

FIG. 10 is a diagram of an illustrative single-track position index strip that may be included in guide rod 22. In the example of FIG. 10, index 72 contains a series of index regions 86. Regions 86 may contain magnetic poles or optical sensing patterns that allow index 72 to be measured by sensor 70 (FIG. 2). As an example, regions 86 may be formed from a series of alternating magnetic poles (e.g., north poles N and south poles S that alternates in a pattern such as N-S-N-S-N . . . along the length of index 72). As another example, regions 86 may contain materials with different reflectivities (and therefore different appearances under visible light and/or under other light such as infrared light). In an illustrative arrangement, regions 86 may contain white regions W (or other light regions) and black regions B (or other dark regions) that alternate in a pattern such as B-W-B-W-B . . . along the length of index 72). Regions 86 may be formed by laser etching, by printing (e.g., with black and white ink or other ink), by mechanical treatment (e.g., scribing, drilling, polishing, etc.), and/or other optical index patterning techniques.

With arrangements such as these, which are sometimes referred to as relative position sensor arrangements, sensor 70 (FIG. 2) may determining the position of sensor 70 (and therefore support 38) along the length of index 72 (and therefore along the length of guide rod 22) by monitoring how many of regions 86 are passed by sensor 70 as optical assembly 20 slides along rod 22. If, for example, sensor 70 passes by N regions 86, it can be concluded that sensor 70 is located a distance equivalent to N regions 86 along the X axis from its starting point. If motor 48 reverses direction, sensor 70 can likewise measure how many of regions 86 are passed by sensor 70 as sensor 70 travels along the −X direction (e.g., if support 38 moves past M regions 86 in the −X direction, the position sensor formed by sensor 70 and index 72 can determine that support 38 is now located at a position that is N-M regions 86 from its original starting point.

Another illustrative configuration for index 72 is shown in FIG. 11. In this type of arrangement, index 72 is a multi-track index having multiple parallel tracks (e.g., track 72-1, 72-2, and 72-3, and additional tracks, if desired). Each of these tracks may be encoded using a different pattern of regions 86. For example, the tracks of index 72 may be formed from parallel strips of alternating magnetic poles or alternating light/dark optical marks where each successive track has a period that is half of the previous track, thereby forming a binary position code across the tracks. As shown in FIG. 12, sensor 70 may have multiple corresponding elements (e.g., sensor element 70-1 for measuring regions 86 in track 72-1, sensor element 70-2 for measuring regions 86 in track 72-2, sensor element 70-3 for measuring regions 86 in track 72-3, etc.). The elements of multi-element sensors such as sensor 70 may be magnetic sensors (each of which measures the magnetic fields produced by alternating north and south magnetic poles associated with regions 86) or optical sensors such as photodetectors (each of which optically measures the light reflected from alternating light/dark regions 86). The regions 86 in the tracks of a multi-track index serve to encode (e.g., in binary) the absolute position of sensor 70 along the length of index 72. By providing a sufficiently large number of tracks in index 72 of FIG. 11, the position sensor can decode the absolute position of sensor 70 (and therefore support 38 and assembly 20) along the length of index 72 (and therefore along the length of guide rod 22) with a desired accuracy. In general, increasing the number of tracks in index 72 will increase positional accuracy (e.g., a larger number of tracks will allow the most fine-grained pattern of regions 86 to exhibit a finer pitch), but will involve the use of correspondingly more sensor elements. Arrangements of the type shown in FIGS. 11 and 12 in which the position sensor determines the absolute position of assembly 20 along guide rod 22 may sometimes be referred to as absolute position sensor arrangements.

Hybrid position sensors may also be used in monitoring the position of assemblies 20. As an example, index 72 may have absolute position index portions 86′ (e.g., bar codes or patterns of magnetic poles that are encoded to provide sensor 70 with binary absolute position information as described in connection with FIGS. 11 and 12) interspersed with relative position index portions (e.g., regions 86 that contain alternating N/S magnetic poles or alternating light/dark patches that serve as optical tic marks). With this type of hybrid approach, sensor 70 can read out the absolute position of sensor 70 along index 72 whenever sensor 70 encounters one of the absolute position indices (one of portions 86′) and can then read out the relative position of sensor 70 with respect to that measured absolute position using adjacent relative position sensor regions 86. In other words, portions 86′ can be used to provide absolute position information at a series of discrete locations, whereas regions 86 between portions 86′ can be used to provide relative position information for positions between portions 86′. Absolute position sensor portions (regions) 86′ may be formed using one-dimensional bar codes or other codes sensed using a one-dimensional array of photodetectors as described in connection with sensor elements 70-1, 70-2, and 70-3 of sensor 70 of FIG. 12 or portions 86′ may contain QR codes or other two-dimensional bar codes that are read using a camera (e.g., sensor 70 may be an image sensor for reading two-dimensional bar codes).

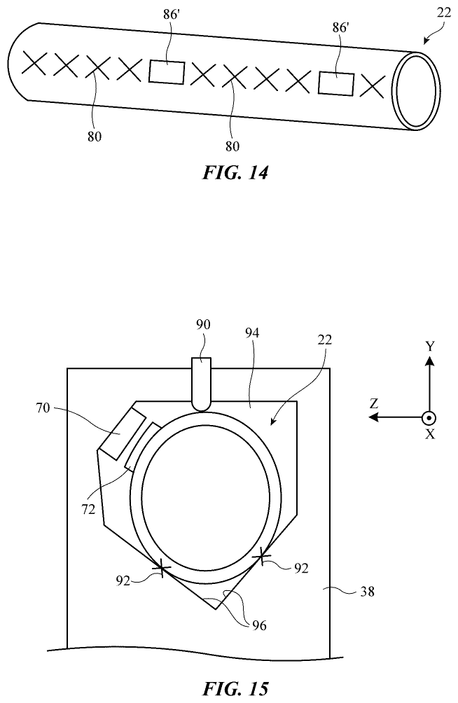

FIG. 14 is a perspective view of an illustrative guide rod 22 having embedded fibers 80 (e.g., glass fibers in a scenario in which rod 22 is a fiberglass rod or carbon fibers in a scenario in which rod 22 is formed from a carbon-fiber tube). Fibers 80 may be woven fibers, knit fibers, braided fibers, or other fibers having a regular spacing (pitch) along the length of the tube of 22. This allows fibers 80 (and the spaces between fibers 80 which have a different optical reflectivity value) to serve as index regions 86. If desired, absolute position index portions (absolute position indices) 86′ may optionally be provided along the length of rod 22 (e.g., in a hybrid arrangement in which absolute index regions are interspersed with relative index regions). In arrangements of the type shown in FIG. 14, fibers 80 may be monitored by a photodetector or other optical sensor 70 as sensor 70 is moved along the length of rod 22, so separately patterned regions (e.g., light/dark regions of printed ink) may be omitted (or may be optionally used in forming absolute position addresses in portions 86′).

FIG. 15 is a cross-sectional end view of an illustrative portion of an optical assembly and associated guide rod. As shown in the illustrative arrangement of FIG. 15, support 38 may have an opening such as opening 94 that receives guide rod 22. A spring-loaded pin such as pin 90 or other biasing component may press guide rod 22 into contact with surfaces 96 of a V-groove formed in support 38. This causes rod 22 to contact surfaces 96 at locations 92, thereby helping to accurately establish a known location for guide rod 22 within support 38. Index 72 may be formed on an inner surface of guide rod 22, may be embedded within a tubular wall or other structure forming guide rod 22, or may, as shown in FIG. 15, be mounted on an exterior surface of guide rod 22. Sensor 70 may be mounted in opening 94 adjacent to and facing index 72, so that sensor 70 can measure regions 86 in index 72 as support 38 moves along guide rod 22 (into and out of the page in the orientation shown in FIG. 15).

To help protect the privacy of users, any personal user information that is gathered by device 10 may be handled using best practices. These best practices including meeting or exceeding any privacy regulations that are applicable. Opt-in and opt-out options and/or other options may be provided that allow users to control usage of their personal data.

The foregoing is merely illustrative and various modifications can be made to the described embodiments. The foregoing embodiments may be implemented individually or in any combination.

What is claimed is:

1. A head-mounted device, comprising:
a head-mounted housing;
guide rods coupled to the head-mounted housing, each guide rod including a respective position index; and
optical assemblies, wherein each optical assembly includes:
a lens;
a display that is configured to provide an image to an eye box through the lens;
a sensor; and
a support for the lens, display, and sensor, wherein the support of each optical assembly is configured to slide along a respective one of the guide rods while the sensor of that optical assembly makes position measurements on the respective position index of that guide rod.

2. The head-mounted device defined in claim 1 wherein the respective position index of each guide rod has regions with different magnetic poles.

3. The head-mounted device defined in claim 2 wherein the sensor of each optical assembly comprises a magnetic sensor.

4. The head-mounted device defined in claim 3 wherein each guide rod comprises a tube and wherein the respective position index of that guide rod comprises a magnetic position index that extends along an exterior surface of the tube.

5. The head-mounted device defined in claim 3 wherein each guide rod comprises a tube having a wall and wherein the respective position index of that guide rod comprises a magnetic position index embedded in the wall.

6. The head-mounted device defined in claim 3 wherein each guide rod comprises a tube having a wall and wherein the respective position index of that guide rod compromises a magnetic position index on an inner surface of the wall.

7. The head-mounted device defined in claim 3 wherein each guide rod has a groove and wherein the respective position index of that guide rod is formed in the groove and extends along that guide rod.

8. The head-mounted device defined in claim 3 wherein each guide rod has a wall formed at least partly from polymer and wherein the respective position index of that guide rod comprises a strip of magnetic particles embedded in the polymer.

9. The head-mounted device defined in claim 3 wherein the support of each optical assembly has an opening configured to receive a respective one of the guide rods and wherein the sensor of that optical assembly is mounted in the opening facing the respective position index.

10. The head-mounted device defined in claim 1 wherein each position index comprises a relative position index that the sensor is configured to monitor to determine a relative position of the sensor along that relative position index.

11. The head-mounted device defined in claim 1 wherein each position index comprises an absolute position index containing coded absolute position information that the sensor is configured to monitor to determine an absolute position of the sensor along the respective one of the guide rods.

12. The head-mounted device defined in claim 1 wherein each position index comprises relative position index regions and absolute position index portions interspersed among the relative position index regions.

13. The head-mounted device defined in claim 1 wherein the respective position index of each guide rod has alternating light and dark regions and wherein the sensor comprises an optical sensor configured to make the position measurements by measuring the alternating light and dark regions.

14. The head-mounted device defined in claim 13 wherein each guide rod has fibers that are configured to form at least part of the light and dark regions of that guide rod.

15. The head-mounted device defined in claim 1 wherein the respective position index of each guide rod has multiple tracks and wherein the sensor of the optical assembly that slides along that guide rod has multiple sensor elements each of which measures a respective one of the multiple tracks.

16. A head-mounted device, comprising:
a head-mounted housing;
a guide rod coupled to the head-mounted housing, wherein the guide rod has a magnetic strip that extends along the guide rod;
a support having an opening configured to receive the guide rod and allow the support to slide along the guide rod;
a display supported by the support;
a lens supported by the support; and
a magnetic sensor supported by the support, wherein the magnetic sensor is configured to measure the magnetic strip to determine where the support is positioned along the guide rod.

17. The head-mounted device defined in claim 16 wherein the magnetic strip comprises a series of regions with alternating north and south magnetic poles and wherein the series of regions extends along the magnetic strip.

18. The head-mounted device defined in claim 17 wherein the magnetic sensor is mounted within the opening.

19. A head-mounted device, comprising:
a head-mounted housing;
a guide rod coupled to the head-mounted housing, wherein the guide rod has light and dark regions;
a support having an opening configured to receive the guide rod and allow the support to slide along the guide rod;
a display supported by the support;
a lens supported by the support; and
an optical sensor configured to measure the light and dark regions to determine where the support is positioned along the guide rod.

20. The head-mounted device defined in claim 19 wherein the light and dark regions alternate in a strip along the guide rod.
